(19) United States
(12) Patent Application Publication
(10) Pub. No.: US 2025/0140607 A1
(43) Pub. Date: May 1, 2025

(54) THERMAL CONDUCTIVE BARRIER LAYER IN INTERCONNECT STRUCTURE

(71) Applicant: Taiwan Semiconductor Manufacturing Company, Ltd., Hsin-Chu (TW)

(72) Inventors: Szu-Hua Chen, Tainan City (TW); Kuan-Kan Hu, Hsinchu (TW); Wei-Yen Woon, Taoyuan City (TW); Szuya Liao, Hsinchu (TW)

(21) Appl. No.: 18/425,264

(22) Filed: Jan. 29, 2024

Related U.S. Application Data
(60) Provisional application No. 63/593,618, filed on Oct. 27, 2023.

(51) Int. Cl. H01L 21/768; H01L 23/522; H01L 23/532

(52) U.S. Cl. CPC H01L 21/76831; H01L 21/76802; H01L 21/7684; H01L 21/76864; H01L 21/76877; H01L 23/5226; H01L 23/53238

(57) ABSTRACT

A method of forming a semiconductor structure includes forming a conductive feature in a first dielectric layer, forming a second dielectric layer over the conductive feature, forming an opening in the second dielectric layer to expose a top surface of the conductive feature, forming an inhibitor film at the top surface of the conductive feature, depositing a thermal conductive layer having a first portion on sidewalls of the opening and a second portion on a top surface of second dielectric layer, removing the inhibitor film to expose the top surface of the conductive feature, depositing a conductive material in the opening and on the second portion of the thermal conductive layer, removing a portion of the conductive material to expose the second portion of the thermal conductive layer, and forming a third dielectric layer on the second portion of the thermal conductive layer and on the second dielectric layer.

### PRIORITY

This is a non-provisional application and claims benefit of U.S. Provisional Patent Application Ser. No. 63/593,618, filed Oct. 27, 2023, the entire disclosure of which is incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. Shrinking sizes and high integration density of semiconductor devices make the heat dissipation challenging. For example, as multilayer interconnect (MLI) structures become more compact with ever-shrinking IC feature size, heat generated in the device layer of an IC may be trapped by the dielectric layers of the MLI structures, which generally have poor thermal conductivity, and cause sharp local temperature peaks, sometimes referred to as thermal hotspots. Thermal hotspots due to heat generated by devices may negatively affect the electrical performance of the IC and often lead to electromigration and reliability issues for electronic components in the IC. Accordingly, although existing MLI structures have been generally adequate for their intended purposes, they have not been entirely satisfactory in all respects. Therefore, there is a need to solve or mitigate the above deficiencies and problems.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a cross-sectional view of layers involved in an interconnect structure of a semiconductor device, in accordance with some embodiments of the present disclosure.

FIGS. 2, 3, 4, 5, 6, 7, 8, 9, 10, 11, 12, 13, and 14 illustrate cross-sectional views of an interconnect structure at intermediate stages in the formation of interconnect layers containing barrier layers, metal lines, and vias, in accordance with some embodiments of the present disclosure.

FIG. 15 shows a process flow for forming an interconnect structure, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

IC manufacturing process flow is typically divided into three categories: front-end-of-line (FEOL), middle-end-of-line (MEOL), and back-end-of-line (BEOL). FEOL generally encompasses processes related to fabricating IC devices, such as transistors. For example, FEOL processes can include forming isolation features, gate structures, and source and drain features (generally referred to as source/drain features). MEOL generally encompasses processes related to fabricating contacts to conductive features (or conductive regions) of the IC devices, such as contacts to the gate structures and/or the source/drain features. BEOL generally encompasses processes related to fabricating a multilayer interconnect (MLI) structure that interconnects IC features fabricated by FEOL and MEOL (referred to herein as FEOL and MEOL features or structures, respectively), thereby enabling operation of the IC devices.

As IC technologies progress towards smaller technology nodes, BEOL process is experiencing significant challenges. For example, advanced IC technology nodes require more effective thermal dissipation paths available in the MLI structure with the significant reduction of critical dimensions of features in the MLI structure. Thermal energy in the form of heat may be generated during the operations of the electrical circuitries, and some types of electrical circuitries may generate more heat than other types of electrical circuitries. When the heat-generating electrical circuitries are closely packed together in an IC, one or more thermal hotspot regions may be formed. These thermal hotspot regions may refer to regions or areas on an IC where more heat is generated per unit area/volume per unit time than other regions of the IC. For example, a thermal hotspot region may have a greater temperature than a region that neighbors the thermal hotspot region during the operation of the IC. Thermal hotspots may be easily formed in an IC if there are less thermal dissipation paths available in the IC. The dielectric layers of the MLI structure generally exhibit poor thermal conductivity, which may not effectively dissipate heat generated from the device layer underneath.

The present disclosure discloses embodiments of interconnect structures that provide vias and metal lines structures (collectively, contact structures) with enhanced thermal dissipation capability. Contact structures often include diffusion barrier layers. The diffusion barrier layer has the function of preventing the diffusion of metal elements (such as copper) in the contact structures from diffusing into dielectric layers surrounding the contact structures. A diffusion barrier layer may also be simply referred to as a barrier layer. Generally, a barrier layer in an MLI structure has poor thermal conductivity. In embodiments of the present disclosure, barrier layers are made of thermal conductive material(s). In the context of the present disclosure, the terms “conductive” and “conductivity” specifically refer to “electrically conductive” and “electrical conductivity,” respectively, to distinguish from the term “thermal conductivity.” A thermal conductive material, as used herein, is defined as a material with a thermal conductivity of not less than 10 W/m·K (Watts per meter-Kelvin). A thermal conductive material is particularly effective at conducting heat. This means the barrier layer made of a thermal conductive material allows heat to pass through it rapidly and efficiently. Further, a diffusion barrier layer of a contact structure may extend along the surface of the respective dielectric layer of the MLI structure to adjoin with other barrier layers from neighboring contact structures in the same interconnect layer of the MLI structure to form a larger heat dissipating plane. Diffusion barrier layers on different interconnect layers of the MLI structure may also be thermally connected through thermal vias to turn the MLI structure into a three-dimensional (3D) heat dissipating network. In some embodiments, a barrier layer is selectively formed on sidewalls of the respective contact structure, but not formed directly on the underlying interconnect features. By not having the barrier layer directly contacting the underlying interconnect feature, heat can also be directly dissipated through metal features in the MLI structure as to provide multiple thermal dissipation paths.

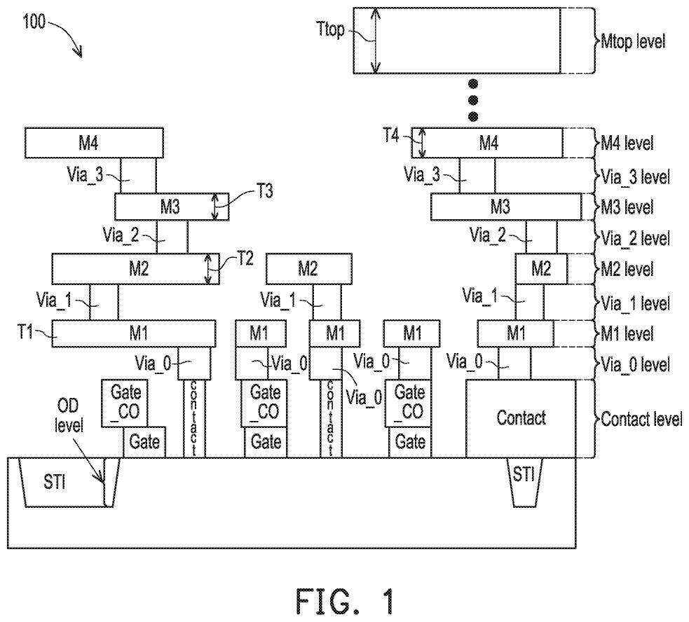

FIG. 1 illustrates a schematic cross-sectional view of a plurality of layers involved in a semiconductor device 100. It is noted that FIG. 1 is schematically illustrated to show various levels of interconnect structure and circuit device regions (e.g., transistors), and may not reflect the actual cross-sectional view of a semiconductor device 100. The interconnect structure includes multiple interconnect levels, such as a contact level, an OD (wherein the term “OD” represents “active region”) level, via levels Via_0 level, Via_1 level, Via_2 level, and Via_3 level, and metal-layer levels M1 level, M2 level, M3 level, M4 level . . . Mtop level. Each of the illustrated interconnect levels includes one or more low-k dielectric layers and the conductive features formed therein. The conductive features that are at the same interconnect level may have top surfaces substantially level to each other, bottom surfaces substantially level to each other, and may be formed simultaneously. The contact level may include gate contacts (also referred to as contact plugs) for connecting gate electrodes of transistors to an overlying level such as the Via_0 level, and source/drain contacts (marked as “contact”) for connecting the source/drain regions of transistors to the overlying level. Thickness of the metal lines at the metal-layer levels M1 level, M2 level, M3 level, M4 level . . . Mtop level are denoted as T1, T2, T3, T4 . . . Ttop, respectively. It is also noted that metal-lines at a higher level generally have a larger thickness than metal lines at a lower level (i.e., T1<T2<T3<T4< . . . <Ttop). Further, metal lines at a higher interconnect level generally have a larger pitch (e.g., center-to-center distance or edge-to-edge distance between adjacent metal lines) than metal lines at a lower level.

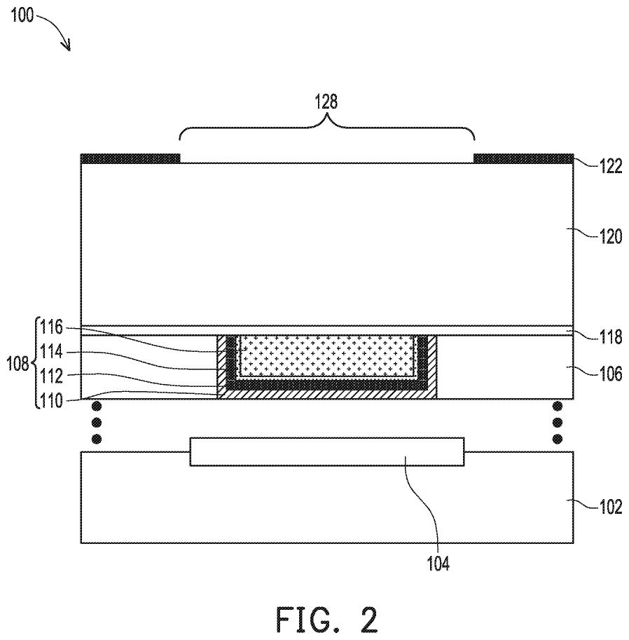

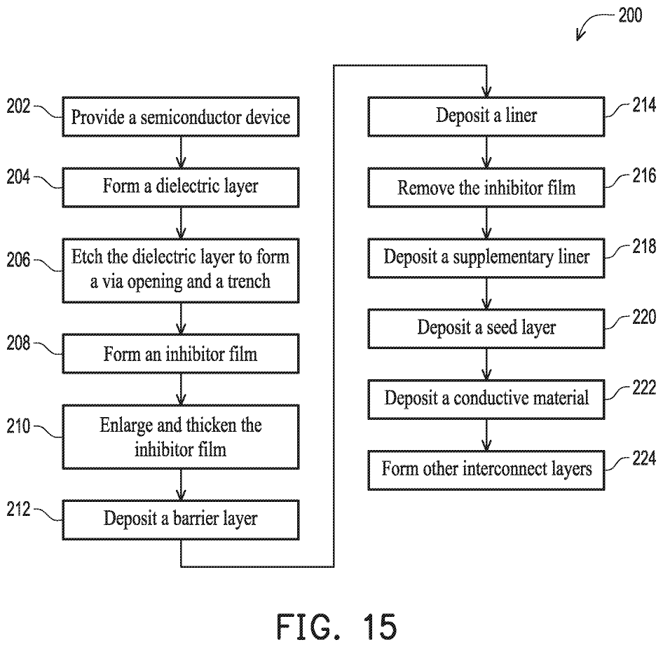

FIGS. 2 through 14 illustrate the cross-sectional views of intermediate stages in the formation of contact structures in the semiconductor device 100 in accordance with some embodiments of the present disclosure. Corresponding processes are also reflected schematically in the process flow 200 as shown in FIG. 15. Additional processes can be provided before, during, and after the process flow 200, and some of the processes described can be moved, replaced, or eliminated for additional embodiments of the process flow 200. Additional features can be added in the interconnect structure depicted in FIGS. 2-14, and some of the features described below can be replaced, modified, or eliminated in other embodiments of the interconnect structure depicted in FIGS. 2-14.

FIG. 2 illustrates a cross-sectional view of the semiconductor device 100. In accordance with some embodiments of the present disclosure, the semiconductor device 100 is a device wafer including active devices such as transistors and/or diodes, and possibly passive devices such as capacitors, inductors, resistors, or the like. In accordance with alternative embodiments of the present disclosure, the semiconductor device 100 is an interposer wafer, which may or may not include active devices and/or passive devices. In accordance with yet alternative embodiments of the present disclosure, semiconductor device 100 is a package substrate strip, which may include package substrates with cores therein or core-less package substrates. In subsequent discussion, a device wafer is used as an example of the semiconductor device 100. The teaching of the present disclosure may also be applied to interposer wafers, package substrates, packages, etc.

In accordance with some embodiments of the present disclosure, the semiconductor device 100 includes a semiconductor substrate 102 and the features formed at a top surface of the semiconductor substrate 102. The semiconductor substrate 102 may comprise crystalline silicon, crystalline germanium, silicon germanium, a III-V compound semiconductor such as GaAsP, AlInAs, AlGaAs, GaInAs, GaInP, GaInAsP, or the like. The semiconductor substrate 102 may also be a bulk silicon substrate or a Silicon-On-Insulator (SOI) substrate. Shallow trench isolation (STI) regions (not shown in FIG. 2, but shown in FIG. 1) may be formed in the semiconductor substrate 102 to isolate the active regions in the semiconductor substrate 102. Although not shown, through-vias may be formed to extend into the semiconductor substrate 102, wherein the through-vias are used to electrically inter-couple the features on opposite sides of the semiconductor device 100.

In accordance with some embodiments of the present disclosure, circuit devices 104 are formed on the top surface of the semiconductor substrate 102. Examples of the circuit devices 104 include complementary metal-oxide semiconductor (CMOS) transistors, resistors, capacitors, diodes, or the like. The details of circuit devices 104 are not illustrated herein.

Further illustrated in FIG. 2 is a dielectric layer 106. The dielectric layer 106 may be an inter-layer dielectric (ILD) layer or an inter-metal dielectric (IMD) layer. In accordance with some embodiments of the present disclosure, the dielectric layer 106 is an ILD layer, in which contact plugs are formed. The corresponding dielectric layer 106 may be formed of Phospho Silicate Glass (PSG), Boro Silicate Glass (BSG), Boron-Doped Phospho Silicate Glass (BPSG), Fluorine-Doped Silicate Glass (FSG), a silicon oxide layer (formed using Tetra Ethyl Ortho Silicate (TEOS)), or the like. Dielectric layer 106 may be formed using spin-on coating, Atomic Layer deposition (ALD), Flowable Chemical Vapor Deposition (FCVD), Chemical Vapor Deposition (CVD), Plasma-Enhanced Chemical Vapor Deposition (PECVD), Low-Pressure Chemical Vapor Deposition (LPCVD), or the like. In accordance with some embodiments of the present disclosure, the dielectric layer 106 is an IMD layer, in which metal lines and/or vias are formed. The corresponding dielectric layer 106 may be formed of a carbon-containing low-k dielectric material, Hydrogen SilsesQuioxane (HSQ), MethylSilsesQuioxane (MSQ), or the like. In accordance with some embodiments of the present disclosure, the formation of the dielectric layer 106 includes depositing a porogen-containing dielectric material, and then performing a curing process to drive out the porogen, and hence the remaining dielectric layer 106 is porous.

A conductive feature 108 is formed in the dielectric layer 106. Conductive feature 108 may be a metal line, a conductive via, a contact plug, or the like. In accordance with some embodiments, conductive feature 108 includes a barrier layer 110, a liner 112, a seed layer 114, and a metal fill layer 116 over the seed layer 114. The barrier layer 110 may be formed of a conductive material such as Ta, TaN, TaC, Ti, TiN, TiC, a dielectric material such as boron nitride, aluminum nitride, aluminum oxide, silicon carbon nitride, silicon carbon oxide, and other suitable material that can block metal element diffusion, and may be deposited using ALD, CVD, ELD, or PVD and may be formed to a thickness between about 1 nm and about 2 nm. The barrier layer 110 may also be referred to as a diffusion barrier layer. In accordance with some embodiments of the present disclosure, the formation of the barrier layer 110 may also adopt the methods as discussed subsequently, so that the barrier layer 110 is alternatively formed of a thermal conductive material (additionally may be electrically non-conductive), and the barrier layer 110 may be not formed under the bottom surface of the conductive feature 108.

The liner 112 is deposited on the barrier layer 110. In some implementations, the liner 112 may be deposited using ALD, CVD, ELD, or PVD and may be formed to a thickness between about 0.5 nm and 3 nm. The liner 112 may be formed of suitable metal, metal nitride, or metal carbide, such as Co, CoN and RuN. In one example, the liner 112 is made of Co. The liner 112 functions to increase adhesion between the seed layer 114 and the barrier layer 110. The liner 112 may also be referred to as an adhesive layer.

The seed layer 114 is formed on the liner 112. In some implementations, the seed layer 114 is a metal alloy layer containing at least a main metal element, e.g., copper (Cu), and an additive metal element, e.g., manganese (Mn). In one example, the seed layer 114 is a copper-manganese (CuMn) layer. In other embodiments, Ti, Al, Nb, Cr, V, Y, Tc, Re, or the like can be utilized as an alternative additive metal for forming the seed layer 114. The concentration (atomic percentage) of the additive metal element in the copper-alloy layer may range from about 0.5% to about 5%, in some embodiments. As explained in further detail below, the concentration of the additive metal element may vary in contact structures at different levels in some embodiments. In one example, the copper-alloy layer is a CuMn layer, and the contact structures at a higher level have a higher concentration of manganese than contact structures at a lower level. The seed layer 114 may be deposited by using ALD, CVD, ELD, PVD, or other suitable deposition techniques.

The metal fill layer 116 may be formed of copper, a copper alloy, aluminum, or the like. The barrier layer 110 has the function of preventing the diffusion of the material (such as copper) in the metal fill layer 116 into the dielectric layer 106. In some embodiments, the metal fill layer 116 may be deposited using PVD, CVD, ALD, electroplating, ELD, or other suitable deposition process, or combinations thereof. After the deposition of the metal fill layer 116, a planarization process such as a Chemical Mechanical Planarization (CMP) process or a mechanical polish process may be performed to remove excess portions of conductive material of the metal fill layer 116.

As also shown in FIG. 2, an etch stop layer 118 is formed over the dielectric layer 106 and the conductive feature 108. The etch stop layer 118 is formed of a material that has a high etching selectivity with relative to the overlying dielectric layer 120, and hence the etch stop layer 118 may be used to stop the etching of the dielectric layer 120. The etch stop layer 118 may comprise a single layer or a stack of layers. In some embodiments, the etch stop layer 118 is formed of a dielectric material, which may include, and is not limited to, aluminum oxide, aluminum nitride, silicon nitride, silicon carbide, silicon oxynitride, silicon oxycarbide, silicon carbo-nitride, silicon oxycarbonitride, silicon methylidyne, hydrogenated oxidized silicon carbon, or a combination thereof. For example, the etch stop layer 118 may include a bottom layer of aluminum nitride, a first middle layer of silicon oxycarbide disposed on the bottom layer, a second middle layer of aluminum oxide disposed on the first middle layer, and a top layer of silicon oxycarbide. In various embodiments, the etch stop layer 118 may have a larger thickness than the liner 112.

A dielectric layer 120 is formed over the etch stop layer 118. The respective process is illustrated as process 204 in the process flow 200 shown in FIG. 15. In accordance with some embodiments, the dielectric layer 120 is an IMD layer or an ILD layer. The dielectric layer 120 may comprise a dielectric material such as an oxide, a nitride, a carbon-containing dielectric material, or the like. For example, the dielectric layer 120 may be formed of silicon oxycarbide, silicon oxide, amorphous boron nitride (a-BN), SiCOH, SiCNH, PSG, BSG, BPSG, FSG, TEOS oxide, HSQ, MSQ, or the like. The dielectric layer 120 may also be a low-k dielectric layer having a low dielectric constant value lower than about 3.5 or lower than about 3.0.

A patterned hard mask 122 is formed over the dielectric layer 120. The patterned hard mask 122 is formed by patterning a hard mask layer to form an opening 128 therein, where the opening 128 defines the pattern of a trench that is to be filled to form a metal line. In accordance with some embodiments of the present disclosure, the patterned hard mask 122 is a metal hard mask formed of titanium nitride, aluminum nitride, or the like.

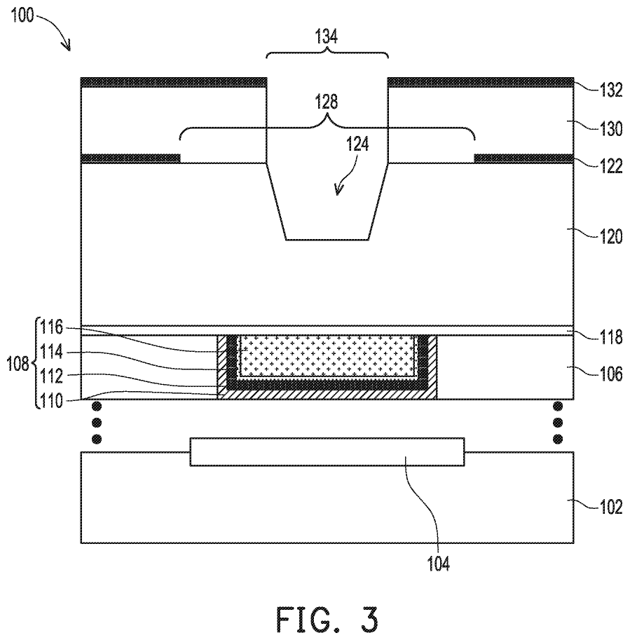

FIGS. 3 through 13 illustrate the process for forming a metal line and a via in accordance with some embodiments. It is appreciated that the examples as shown in FIGS. 3 through 13 recite a dual damascene process. In accordance with alternative embodiments, a single damascene process, in which a metal line, a via, a contact plug, or the like, is formed, which is also contemplated. Particularly, for the sake of simplicity, FIGS. 2 through 13 illustrate the cross-sectional views of intermediate stages in the formation of two consecutive metal-layer levels and the corresponding via level therebetween (e.g., a Mₓ level, a Via_x level, and a Mₓ₊₁ level, x representing an integer) of the interconnect structure of the semiconductor device 100 in accordance with some embodiments.

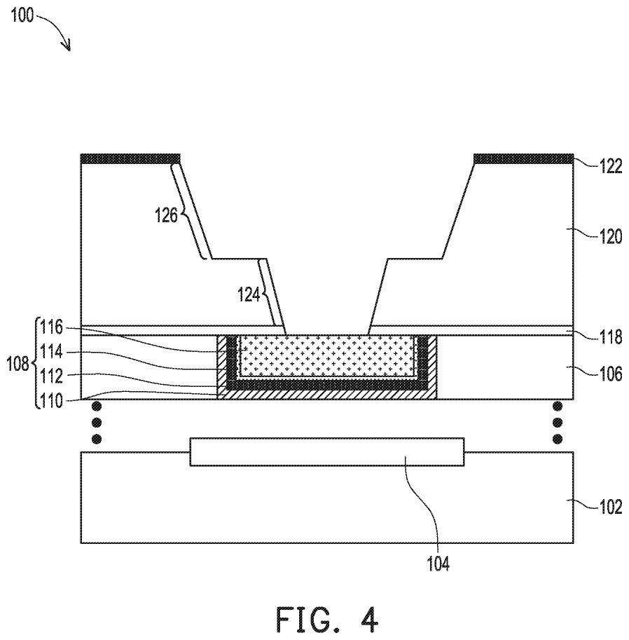

As shown in FIGS. 3 and 4, a via opening 124 and a trench 126 are formed through etching. The respective process is illustrated as process 206 in the process flow 200 shown in FIG. 15. The via opening 124 and the trench 126 may be formed using, for example, photolithography techniques. In an example of the formation process of the via opening 124 and the trench 126, a bottom anti-reflective coating (BARC) layer 130 is formed on the patterned hard mask 122, and a patterned hard mask 132 is formed on the BARC layer 130. In one example, the BARC layer 130 includes organic BARC material formed by a spin-coating technique. The patterned hard mask 132 is formed by patterning a hard mask layer to form an opening 134 therein, where the opening 134 defines the pattern of the via opening 124 that is to be filled to form a via. Through the opening 134, the BARC layer 130 is etched to form the via opening 124. With the via opening 124 extending downward in the etching process, the dielectric layer 120 are then etched.

In accordance with some embodiments of the present disclosure, the etching of the dielectric layer 120 is performed using a process gas comprising fluorine and carbon, wherein fluorine is used for etching, with carbon having the effect of protecting the sidewalls of the resulting opening. With an appropriate fluorine and carbon ratio, the via opening 124 may have a desirable profile. For example, the process gases for the etching include a fluorine and carbon-containing gas(es) such as C₄F₈, CH₂F₂, and/or CF₄, and a carrier gas such as N₂. In an example of the etching process, the flow rate of C₄F₈ is in the range between about 0 sccm and about 50 sccm, the flow rate of CF₄ is in the range between about 0 sccm and about 300 sccm (with at least one of C₄F₈ having a non-zero flow rate), and the flow rate of N₂ is in the range between about 0 sccm and about 200 sccm. In accordance with alternative embodiments, the process gases for the etching include CH₂F₂ and a carrier gas such as N₂. In an example of the etching process, the flow rate of CH₂F₂ is in the range between about 10 sccm and about 200 sccm, and the flow rate of N₂ is in the range between about 50 sccm and about 100 sccm.

During the etching process, the semiconductor device 100 may be kept at a temperature in the range between about 30° C. and about 60° C. In the etching process, plasma may be generated from the etching gases. The Radio Frequency (RF) power of the power source for the etching may be lower than about 700 Watts, and the pressure of the process gases is in the range from about 15 mTorr and about 30 mTorr.

The etching for forming the via opening 124 may be performed using a time-mode. As a result of the etching, the via opening 124 is formed to extend to an intermediate level between the top surface and the bottom surface of the dielectric layer 120. Next, the BARC layer 130 and the patterned hard mask 132 are removed, followed by the further etching of the dielectric layer 120 using the patterned hard mask 122 as an etching mask. In the etching process, which is an anisotropic etching process, the via opening 124 extends down until the etch stop layer 118 is exposed. At the same time the opening 124 is extended downwardly, the trench 126 is formed to extend into the dielectric layer 120. The etch stop layer 118 is subsequently etched with a suitable etchant, and the metal fill layer 116 is exposed at the bottom of the via opening 124. The resulting structure is illustrated in FIG. 3. In the resulting structure, the via opening 124 is underlying and connected to the trench 126.

In accordance with alternative embodiments, the via opening 124 and the trench 126 are formed in separate photo lithography processes. For example, in a first photo lithography process, the via opening 124 is formed extending down to the etch stop layer 118. In a second lithography process, the trench 126 is formed. The order for forming the via opening 124 and the trench 126 may also be inversed. After the forming of the via opening 124 and the trench 126, the patterned hard mask 122 may be removed, such as in an etch process.

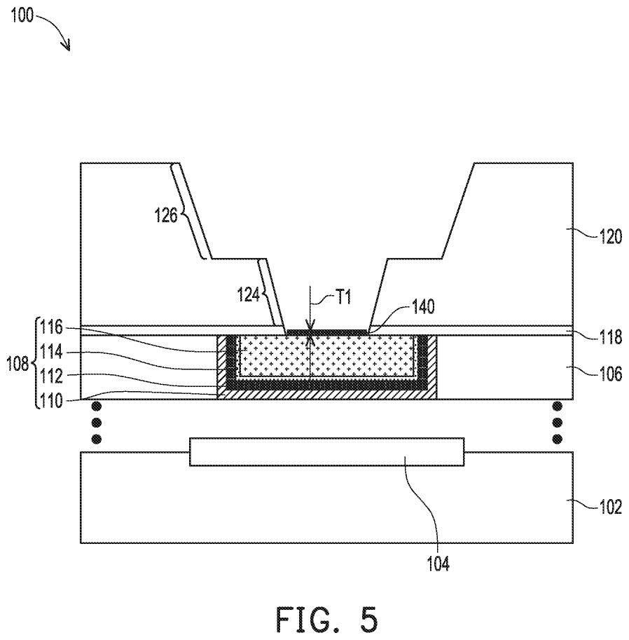

Next, referring to FIG. 5, an inhibitor film 140 is formed. The inhibitor film 140 may be selectively deposited over the metal fill layer 116, without being deposited on the dielectric layer 120. The respective process is illustrated as process 208 in the process flow 200 shown in FIG. 15. In some embodiments, a pre-treatment is performed, for example, using an acid, which may be a diluted hydro fluoride (HF) solution. The pre-treatment may also be performed using a mixed gas of NH₃ (ammonia) and NF₃ (nitrogen trifluoride). Next, the semiconductor device 100 is further treated in a treatment step, and the dangling bonds generated (during the pre-treatment) on the surface of the metal fill layer 116 are terminated to generate the inhibitor film 140. The attached bonds/material may include Si(CH₃)₃ in accordance with some embodiments. The process gas may include Bis(trimethylsilyl)amine, hexamethyldisilalanc (HMDS), tctramethyldisilazane (TMDS), trimethylchlorosilane (TMCS), dimethyldichlorosilane (DMDCS), methyltrichlorosilane (MTCS), or the like, for example. The respective process for attaching the bonds may include a silylation process. In some embodiments, the inhibitor film 140 may be a silane, a phosphonic acid, an organic polymer (such as a polyimide (PI), a polyamide, or the like), or the like. In some embodiments, the inhibitor film 140 may be formed of an organic compound having from 8 to 20 carbon atoms. Specific examples of materials that may be used for the inhibitor film 140 include dodecylsilane (C₁₂H₂₈Si), octadecylphosphonic acid (ODPA, C₁₈H₃₉O₃P), pyromellitic dianhydride (C₁₀H₂O₆), 1,6-diaminohexanc (H₂N(CH₂)₆NH₂), ethylenediamine (C₂H₈N₂), adipoyl chloride (C₆H₈C₁₂O₂), or the like. The resulting inhibitor film 140 may be very thin, and may only include some terminating bonds. In one example, the inhibitor film 140 may be a monolayer of the inhibitor such as a monolayer of benzotriazole (BTA). In other examples, the inhibitor film 140 may have a thickness T1 in the range between about 1 nm and about 2 nm, while the thickness T1 may be greater or smaller.

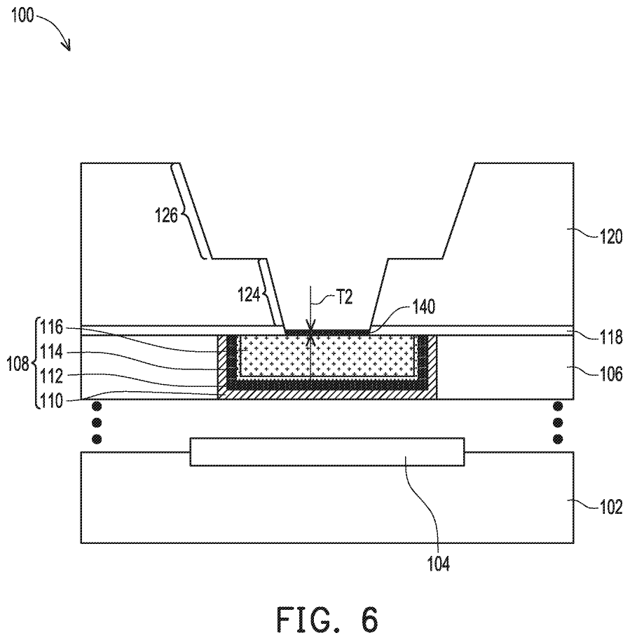

Referring to FIG. 6, in accordance with some embodiments of the present disclosure, to increase the coverage of the inhibitor film 140, an additional inhibitor film formation process is performed. The respective process is illustrated as process 210 in the process flow 200 shown in FIG. 15. In an example of the processes, the semiconductor device 100 is taken out of the wet cleaning solution and soaked in an inhibitor-forming solution. Since this process is used for further growing the inhibitor film 140, but not for causing erosion to the metal fill layer 116, the chemicals that are used for wet cleaning are not included in the inhibitor-forming solution. For example, amine and H₂O₂ may not be included. Some other chemicals such as glycol, dimethyl sulfide, etc., however, may be added in the inhibitor-forming solution. An inhibitor (such as HMDS, ODPA, or BTA), which may be the same or different from the inhibitor used in the wet cleaning solution, is added into the inhibitor-forming solution. The semiconductor device 100 is then soaked in the inhibitor-forming solution to further grow, and to increase the coverage of, the inhibitor film 140. In accordance with some embodiments of the present disclosure, the soaking time is in the range between about 30 seconds and about 60 seconds. After the soaking, the inhibitor film 140 may achieve 100% coverage with the thickness increasing from T1 to T2 (T2>T1). In some embodiments, T2 is at least 50% larger than T1. When the BTA used in the inhibitor-forming solution is different from the BTA used in the wet cleaning solution, the further grown inhibitor film 140 may have a first layer of a first BTA with a thickness of T1 and a second layer of a second BTA with a thickness of T2-T1 with an observable interface between the first layer and the second layer. In various embodiments, the thickened inhibitor film 140 is still thinner than either of the barrier layer 110, the liner 112, and the etch stop layer 118. As to be discussed below that the inhibitor film 140 confines the subsequently formed barrier layer to grow on surfaces that are not covered by the inhibitor film 140, such as on top and sidewall surfaces of the dielectric layer 120.

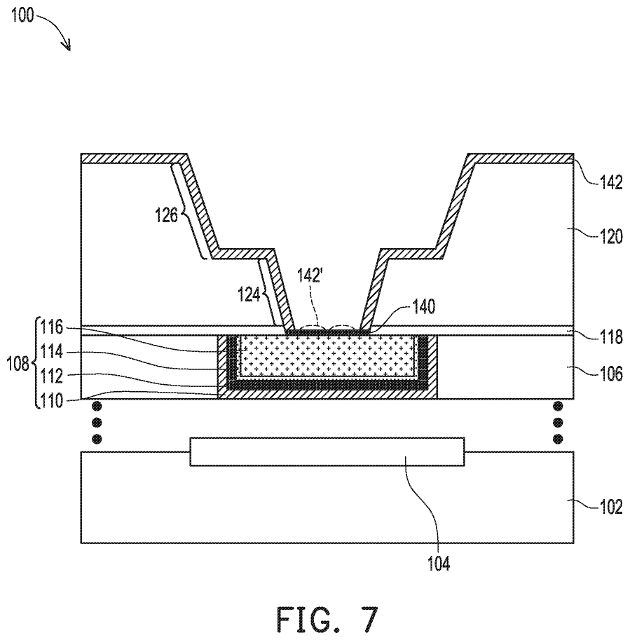

Next, referring to FIG. 7, a thermal conductive layer 142 is deposited lining the via opening 124, the trench 126, and the top surface of the dielectric layer 120. The thermal conductive layer 142 also functions as a diffusion barrier layer that prevents the diffusion of metal elements (such as copper) in the subsequently formed contact structures from diffusing into the dielectric layer 120. Accordingly, the thermal conductive layer 142 is also referred to as diffusion barrier layer 142 or simply as barrier layer 142. In accordance with some embodiments of the present disclosure, a material of the barrier layer 142 may include hexagonal boron nitride (h-BN), aluminum nitride (AlN), graphene, transition metal dichalcogenides (TMDs) (e.g., MoS₂, MoSc₂, WS₂ or WSe₂), or the like. For aluminum nitride, it exhibits a high thermal conductivity of about 370 W/m·K. For graphene, it exhibits a high thermal conductivity above 3500 W/m·K. For TMDs, it generally exhibits a thermal conductivity above 10 W/m·K. For h-BN, it is in a layered structure in a crystalline form similar to graphite and exhibits an in-plane thermal conductivity above 390 W/m·K at room temperature. As a comparison, amorphous BN (a-BN) is in a non-crystalline amorphous form and only exhibits an in-plane thermal conductivity around 3 W/m·K, which is not considered as a thermal conductive material in the context of the present disclosure. In one example, the dielectric layer 120 is formed of a-BN, while the barrier layer 142 is formed of h-BN. In various embodiments, the thermal conductivity of the barrier layer 142 is greater than 10 W/m. K. This threshold is not trivial. As if the thermal conductivity is less than about 10 W/m. K, the barrier layer 142 may not effectively dissipate heat out. When the barrier layer 142 is formed of h-BN, aluminum nitride, or the like, the barrier layer 142 is an electrical insulating and thermal conductive layer.

In some embodiments, the barrier layer 142 is a two-dimensional (2D) material layer. As widely accepted in the art, “2D material” may also be referred to as a “monolayer” material. The 2D material layer 142 may be 2D materials of suitable thickness. In some embodiments, a 2D material includes a single layer of atoms in each of its monolayer structure, so the thickness of the 2-D material refers to a number of monolayers of the 2D material, which can be one monolayer or more than one monolayer. The coupling between two adjacent monolayers of 2D material includes van der Waals forces, which are weaker than the chemical bonds between/among atoms within the single monolayer. That is, the 2D material layer 142 may be a single-layer or may be a few layers thick and exist as stacks of strongly bonded layers with weak interlayer van der Waals attraction, allowing the layers to be mechanically or chemically exfoliated into individual, atomically thin layers. The 2D material layer 142 can have a thickness ranging from about 1 nm to about 2 nm in some embodiments.

The deposition of the barrier layer 142 may include a plasma-enhanced atomic layer deposition (PE-ALD) process or a chemical vapor deposition (CVD) process. In a PE-ALD process, the deposition is achieved by using alternating cycles of precursor gas and plasma exposure. Exemplary steps of one cycle of the PE-ALD process includes, after loading the semiconductor device 100 into a chamber of the tool performing the PE-ALD process, flowing a precursor gas into the chamber. The precursor gas molecules adsorb onto the surface of the semiconductor device 100, forming a self-limiting monolayer. After the precursor gas exposure, a purge process is performed to purge the precursor gas and any by-products from the chamber. A plasma treatment process that involves flowing a gas into the chamber with charged ions is then performed. During the plasma treatment process, an electromagnetic field, a radiofrequency (RF), or other suitable energy source is applied to direct the ions toward the semiconductor device 100. The plasma breaks down the precursor molecules and initiates chemical reactions on the surface of the semiconductor device 100, leading to film growth. The plasma species react with the precursor monolayer on the semiconductor device, resulting in the formation of a thin film. The ionized gas may be removed from the chamber before the next layer deposition cycle is performed. When the barrier layer 142 is formed of h-BN, the precursor may be borazine (B₃H₆N₃), 1,3,5-Trimethylborazine (C₃H₉B₃N₃), or a combination thereof, and the reactant gas may be N₂ plasma, NH₃ plasma, or a combination thereof. Using borazine (B₃H₆N₃) and/or 1,3,5-Trimethylborazine (C₃H₉B₃N₃) as precursor allows the PE-ALD process to perform at a relatively low temperature, such as between about 200° C. and about 400° C. This is mainly due to the existing B—N ring-like structure in borazine and 1,3,5-Trimethylborazine. As a comparison, if the precursor uses a non-ring-containing molecule, such as borane (BH₃), the reaction temperature may have to be raised above 1000° C. However, BEOL process generally requires a processing temperature less than about 500° C., otherwise low-k dielectric layers in the MLI structure may be damaged by the excessively high temperature above 500° C. Similarly, the barrier layer 142 may be deposited in a CVD process, in which the precursor containing borazine (B₃H₆N₃), 1,3,5-Trimethylborazine (C₃H₉B₃N₃), or a combination thereof, may directly react with the reactant gas containing N₂ plasma, NH₃ plasma, or a combination thereof, followed by a purge process to form the barrier layer 142.

The inhibitor film 140 blocks or delays the growth of the barrier layer 142 in the bottom of the via opening 124. This is mainly due to the steric hindrance of the inhibitor film 140, and the steric hindrance is at least partially due to its heterocyclic structure. For example, on the inhibitor film 140, there is a very small possibility of having a h-BN molecule (assuming the barrier layer 142 is formed of h-BN) grown thereon in an ALD cycle, while on the dielectric layer 120, a full layer of h-BN is grown in each ALD cycle. Accordingly, after one ALD cycle, a very small percentage of the exposed surface of the inhibitor film 140 has the h-BN grown thereon, which acts as the seed for the subsequent growth. After each cycle, a very small additional area of the inhibitor film 140 is covered by the newly grown h-BN. Accordingly, a large percentage of the inhibitor film 140 does not have h-BN grown thereon until after multiple ALD cycles. This effect is referred to as growth delay (or incubation delay) on the inhibitor film 140, while there is no grow delay on surfaces of the dielectric layer 120 since the inhibitor film 140 is not formed on the dielectric layer 120.

Due to the growth delay, and the random seeding of the barrier layer 142 on the inhibitor film 140, after the formation of the barrier layer 142 is finished, there may be substantially no h-BN grown on the inhibitor film 140. Alternatively stated, the barrier layer 142 may not extend onto the inhibitor film 140. It is possible that a small amount of the barrier layer 142 is grown on the inhibitor film 140, with the coverage less than about 20% of the exposed surface of the inhibitor film 140. In accordance with some embodiments, the barrier layer 142 forms discrete islands 142′ on the surface of the inhibitor film 140.

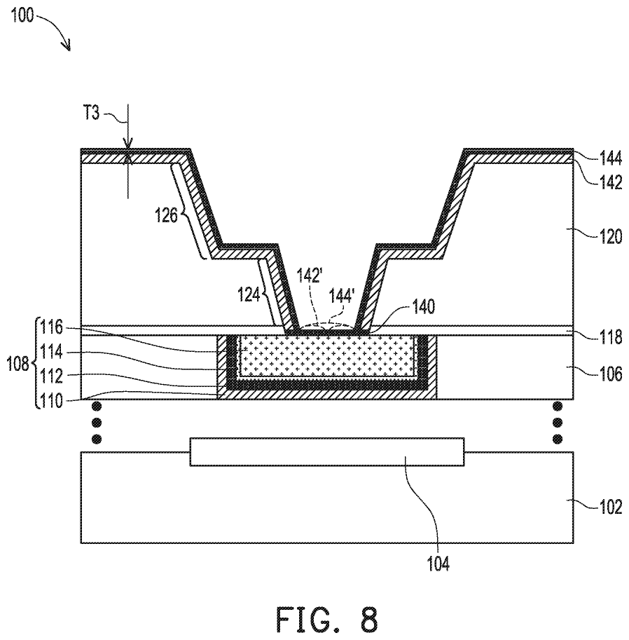

Referring to FIG. 8, a liner 144 is deposited on the barrier layer 142 and lining the via opening 124, the trench 126, and the top surface of the dielectric layer 120, for example, using ALD. The respective process is illustrated as process 214 in the process flow 200 shown in FIG. 15. The liner 144 may be formed of suitable metal, metal nitride, or metal carbide, such as Co, CON and RuN. In furtherance of some embodiments, the liner 144 and the liner 112 have the same material composition. For example, both the liner 144 and the liner 112 may be formed of Co. After the formation of the liner 144, a thickness T3 of the liner 144 may range from about 5 Å to about 10 Å.

The inhibitor film 140 also blocks or delays the growth of the liner 144 in the bottom of the via opening 124. This is due to the steric hindrance of the inhibitor film 140, and the steric hindrance is at least partially due to its heterocyclic structure. For example, on the inhibitor film 140, there is a very small possibility of having a Co-containing material (assuming the liner 144 comprises Co) grown thereon in an ALD cycle, while on the barrier layer 142, a full layer of Co-containing material is grown in each ALD cycle. Accordingly, after one ALD cycle, a very small percentage of the exposed surface of the inhibitor film 140 has the Co-containing material grown thereon, which acts as the seed for the subsequent growth. Once the Co-containing material is grown, the Co-containing material will grow at the same rate as on the barrier layer 142. After each cycle, a very small additional area of the inhibitor film 140 is covered by the newly grown Co-containing material. Accordingly, a large percentage of the inhibitor film 140 does not have Co-containing material grown thereon until after multiple ALD cycles. As a comparison, there is no grow delay on sidewalls of the barrier layer 142 since the inhibitor film 140 is not formed on the barrier layer 142.

Due to the growth delay, and the random seeding of the liner 144 on the inhibitor film 140, after the formation of the liner 144 is finished, there may be substantially no Co-containing material grown on the inhibitor film 140. Alternatively stated, the liner 144 may not extend onto the inhibitor film 140. It is possible that a small amount of the liner 144 is grown on the inhibitor film 140, with the coverage smaller than 20% % of the exposed surface of the inhibitor film 140. In accordance with some embodiments, the liner 144 forms discrete islands 144′ on the surface of the inhibitor film 140, which have random and irregular patterns. Also as depicted in FIG. 8, some discrete islands 144′ of Co-containing material may overlap on the discrete islands 142′ of h-BN from the barrier layer 142.

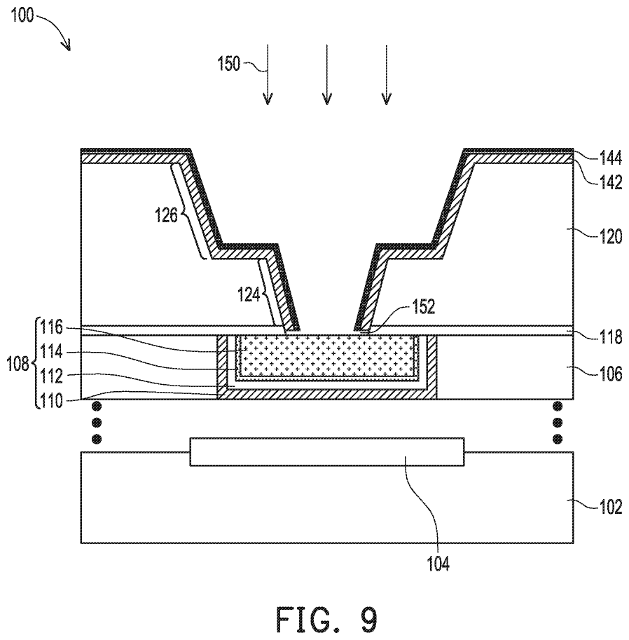

Referring to FIG. 9, a post-deposition treatment 150 is performed to remove the inhibitor film 140. The respective process is illustrated as process 216 in the process flow 200 shown in FIG. 15. The post-deposition treatment 150 may be performed through a plasma treatment. The process gas may include hydrogen (H₂) and a carrier gas such as argon. During the plasma treatment, the temperature of the semiconductor device 100 may be higher than about 200° C., for example, in the range between about 200° C. and about 300° C. The treatment duration may be in the range between about 30 seconds and about 60 seconds. The plasma treatment is also referred to as a plasma de-blocking treatment. As a result of the post-deposition treatment, the inhibitor film 140 is removed, together with the discrete islands 142′ and 144′. In the post-deposition treatment 150, the inhibitor film 140 is decomposed into gases, which are removed. With the inhibitor film 140 being removed, a gap 152 is formed between the metal fill layer 116 and the end portions of the barrier layer 142 and the liner 144. A bottom portion of the sidewalls of the etch stop layer 118 is exposed by the gap 152. The sidewalls of the dielectric layer 120 remains covered by the barrier layer 142. An advantageous feature of performing the post-deposition treatment after the deposition of the barrier layer 142 is that the high-resistive barrier layer 142 would not exist in the bottom of the via opening 124.

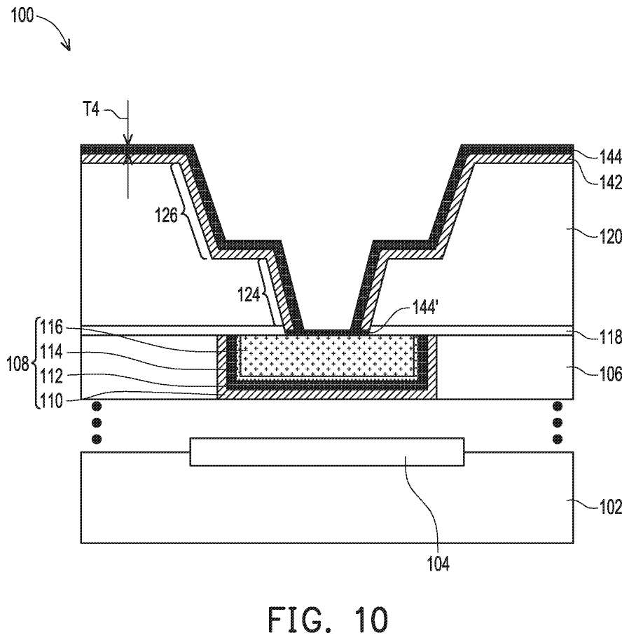

Referring to FIG. 10, a supplementary liner 144′ is conformally deposited on the liner 144 and lining the via opening 124, the trench 126, and the top surface of the dielectric layer 120, for example, using ALD. The respective process is illustrated as process 218 in the process flow 200 shown in FIG. 15. The supplementary liner 144′ also fills the gap 152. The supplementary liner 144′ covers the portion of the top surface of the metal fill layer 116 that is exposed in the via opening 124 and covers the portion of the sidewalls of the etch stop layer 118 exposed in the gap 152. The supplementary liner 144′ may be formed of suitable metal, metal nitride, or metal carbide, such as Co, CON and RuN. In furtherance of some embodiments, the supplementary liner 144′ and the liner 144 have the same material composition. For example, both the supplementary liner 144′ and the liner 144 may be formed of Co. A thickness of the supplementary liner 144′ may be smaller than the thickness T3 of the liner 144. In the embodiments that the supplementary liner 144′ and the liner 144 are formed of the same conductive material, the supplementary liner 144′ merges with the liner 144, and equivalently the liner 144 is thickened to a thickness T4 that is larger than the initial thickness T3. In some embodiments, the thickness T4 is about 30% to 80% larger than the initial thickness T3. The thickened liner 144 helps reducing contact resistance. In the embodiments that the supplementary liner 144′ and the liner 144 are made of different conductive material compositions, an observable interface exists between the two different conductive materials. By filling the gap 152, the liner 144 separates the barrier layer 142 from contacting the metal fill layer 116.

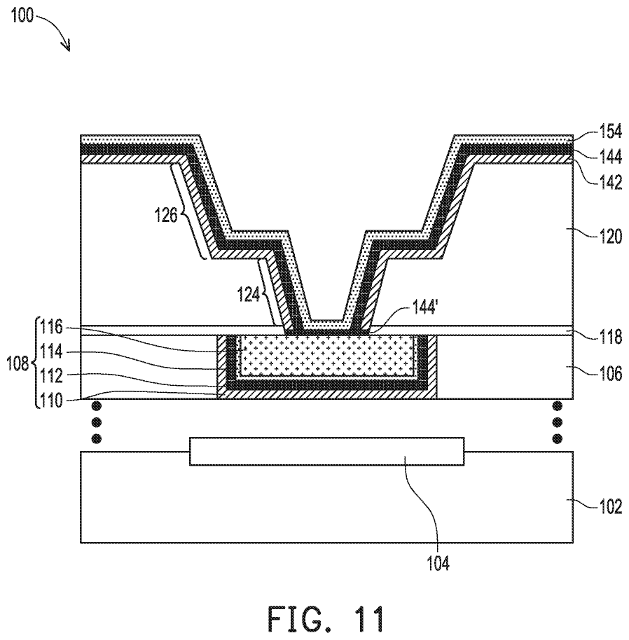

Referring to FIG. 11, a seed layer 154 is formed on the liner 144. The respective process is illustrated as process 220 in the process flow 200 shown in FIG. 15. In some implementations, the seed layer 154 is a metal alloy layer containing at least a main metal element, e.g., copper (Cu), and an additive metal element, e.g., manganese (Mn). In one example, the seed layer 154 is a copper-manganese (CuMn) layer. In other embodiments, Ti, Al, Nb, Cr, V, Y, Tc, Re, or the like can be utilized as an alternative additive metal for forming the seed layer 154. The additive metal element helps improving device electron migration performance. The concentration (atomic percentage) of the additive metal element in the copper-alloy layer may range from about 0.5% to about 5%, in some embodiments. The concentration of the additive metal element in contact structures at a lower metal-layer level may be smaller that of contact structures at a higher metal-layer level. In one example, the copper-alloy for the seed layer 154 and the seed layer 114 is CuMn, and a concentration of manganese in the lower seed layer 114 is smaller than a concentration of manganese in the upper seed layer 154, for example, 1% smaller. This is because, although a higher concentration of additive metal element further helps improving the electron migration performance, a contact resistance is also increased due to the relatively-low resistance of the additive metal element. For conductive features formed in a lower metal-layer level, the generally smaller metal line width and metal line pitch already increase the metal resistance at the lower metal-layer level, and thus a smaller concentration of additive metal element mitigates further increasing the metal resistance. For conductive features formed in a higher metal-layer level, the generally larger metal line width and metal line pitch accommodate a larger concentration of additive metal element without much concern of deteriorating the metal resistance. The seed layer 154 may be deposited by using ALD, CVD, ELD, PVD, or other suitable deposition techniques.

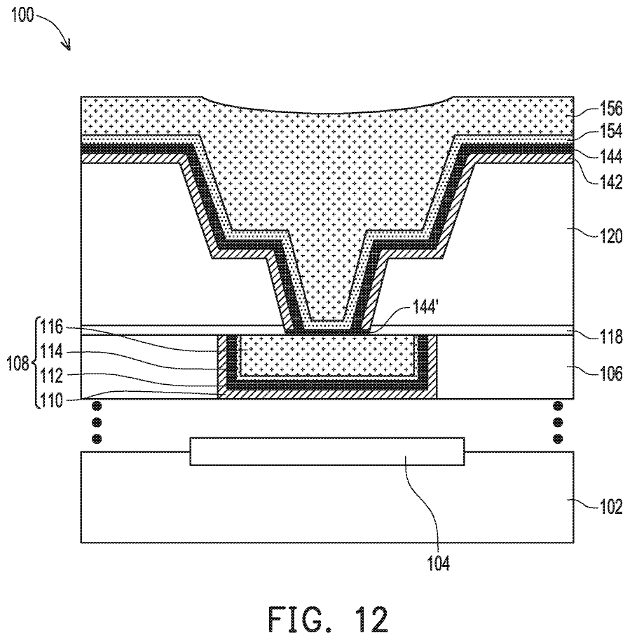

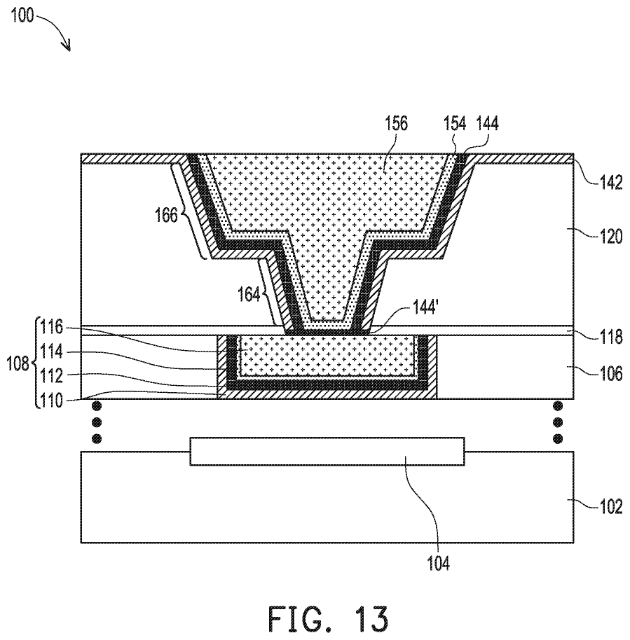

Referring to FIG. 12, a conductive material 156 is deposited to fill the via opening 124 and trench 126. The respective process is illustrated as process 222 in the process flow 200 shown in FIG. 15. The processes as shown in FIGS. 11 and 12 may be in-situ performed in a same vacuum environment, with not vacuum break in between. A part or all of the deposition process in FIGS. 7 through 10 may also be performed in-situ in the same vacuum environment as the processes shown in FIGS. 11 and 12, with no vacuum break in between. In accordance with some embodiments, the deposition of the seed layer 154 includes performing a blanket deposition using Physical Vapor Deposition (PVD), and filling the rest of the via opening 124 and the trench 126 using, for example, electro-plating. A planarization process such as a Chemical Mechanical Planarization (CMP) process or a mechanical polish process may be performed to remove excess portions of conductive material 156, hence forming a via 164 and a metal line 166, as shown in FIG. 13.

Still referring to FIG. 13, the planarization process may use the barrier layer 142 as a planarization stop layer. In other words, after the removal of the excess portions of the conductive material 156, seed layer 154, and the liner 144 from above the top surface of the dielectric layer 120, the barrier layer 142 is exposed. By keeping the horizontal portions of the barrier layer 142 on the top surface of the dielectric layer 120, the barrier layer 142 not only conducts heat from the conductive feature 108 from one interconnect layer below upwardly to the next interconnect layer but also spreads heat horizontally along the top surface of the dielectric layer 120. The heat dissipating surface is significantly expanded. The barrier layer 142 has a thickness ranging from about 1 nm to about 2 nm. This range is not trivial. If the thickness of the barrier layer 142 is less than about 1 nm, the barrier layer 142 may be too thin to effectively dissipate heat away; if the thickness of the barrier layer 142 is larger than about 2 nm, the thick barrier layer 142 may occupy too much precious space inside the via 164 and the overall resistance of the via 164 may increase and the circuit speed may be compromised.

Due to the selective formation of the barrier layer 142, the barrier layer 142 includes the portions contacting the dielectric layer 120 to perform the diffusion-blocking function, and does not have portions to interpose between the liner 144 (the supplementary liner 144′) and the metal fill layer 116 in the bottom of the via 164. Since the barrier layer 142 may be non-conductive or has a low conductivity, not forming the barrier layer 142 at the interface with the underneath contact structures may significantly reduce the contact resistance of the via 164.

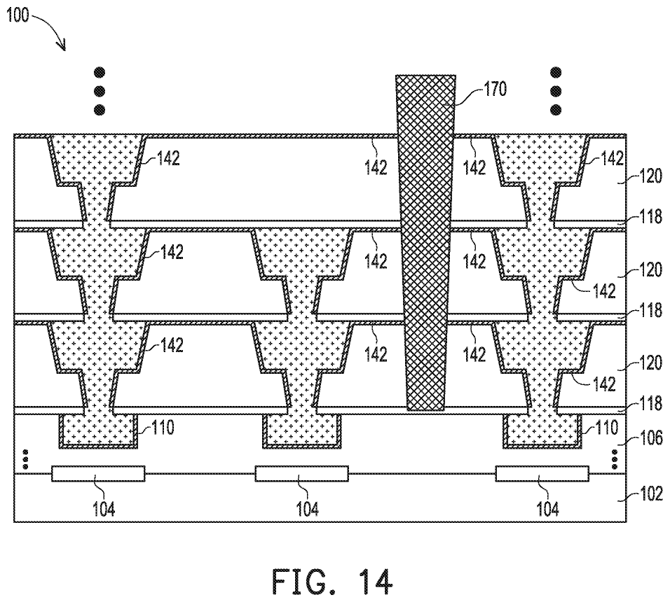

After the formation of the via 164 and the metal line 166, other interconnect layers of the MLI structure may be subsequently deposited above the dielectric layer 120 to form the upper portion of the MLI structure. The respective process is illustrated as process 224 in the process flow 200 shown in FIG. 15. FIG. 14 illustrates a cross-sectional view of the semiconductor device 100 with multiple interconnect layers of the MLI structure that have been formed. For the sake of simplicity, the liner 144 and the seed layer 154 formed in the contact structures are not individually displayed. The barrier layer 142 in each respective interconnect layer conveys heat upwardly from the conductive structure in the underneath interconnect layer and spreads heat out horizontally in the plane of the respective interconnect layer. Further, if the barrier layer 142 is formed of an electrical insulating material, horizontal portions of the barrier layer 142 of vias and metal lines in the same interconnect layer may adjoin to form a continuous thermal dissipating plane. Still further, thermal conductive vias 170, such as through-substrate vias (TSVs) made of thermal conductive material, may be formed through multiple interconnect layers with direct contacts with the horizontal portions of the barrier layers 142 from different interconnect layers in forming a 3D heat dissipating network. The 3D heat dissipating network allows heat generated in the circuitry to be dissipated away more effectively. The thermal conductive vias 170 may be formed of the same or different thermal conductive materials with the barrier layers 142. For example, the thermal conductive vias 170 and the barrier layers 142 may both include h-BN. In another example, the thermal conducive vias 170 may include aluminum nitride, and the barrier layers 142 may includes h-BN.

The embodiments of the present disclosure have some advantageous features. By forming the thermal conductive barrier layer after the formation of the inhibitor film, since the growth of the inhibitor film on different materials is selective, the resulting thermal conductive barrier layer is selectively formed on the sidewalls of the low-k dielectric layer to not only perform the diffusion-blocking function, and also promote thermal performance, prevent potential overheating, and aid in prolonging the device's lifespan and maintaining the device's operational efficiency.

In one exemplary aspect, the present disclosure is directed to a method of manufacturing a semiconductor structure. The method includes forming a conductive feature in a first dielectric layer, forming a second dielectric layer over the conductive feature, forming an opening in the second dielectric layer to expose a top surface of the conductive feature, forming an inhibitor film at the top surface of the conductive feature, depositing a thermal conductive layer having a first portion on sidewalls of the opening and a second portion on a top surface of second dielectric layer, removing the inhibitor film to expose the top surface of the conductive feature, depositing a conductive material in the opening and on the second portion of the thermal conductive layer, removing a portion of the conductive material to expose the second portion of the thermal conductive layer, and forming a third dielectric layer on the second portion of the thermal conductive layer and on the second dielectric layer. In some embodiments, the depositing of the thermal conductive layer includes a reaction between a precursor and a reactant gas, and wherein the precursor includes a molecule containing a boron-nitride ring-like structure. In some embodiments, the molecule is a borazine or a 1,3,5-Trimethylborazine. In some embodiments, the reaction is conducted in a temperature less than about 500° C. In some embodiments, the thermal conductive layer includes hexagonal boron nitride. In some embodiments, the method further includes prior to the depositing of the conductive material, depositing a liner on the thermal conductive layer. The liner fills a gap between the thermal conductive layer and the conductive feature formed after the removing of the inhibitor film. In some embodiments, the liner separates the thermal conductive layer from physically contacting the conductive feature. In some embodiments, the forming of the inhibitor film includes forming an initial inhibitor layer in a first solution, and thickening the initial inhibitor layer to form the inhibitor film in a second solution that is different from the first solution. In some embodiments, the thermal conductive layer separates the third dielectric layer from physically contacting the second dielectric layer. In some embodiments, the thermal conductive layer is configured to block a metal element in the conductive material from diffusing into the second dielectric layer.

In another exemplary aspect, the present disclosure is directed to a method of forming a semiconductor structure. The method includes forming an etch stop layer over a substrate, depositing a dielectric layer over the etch stop layer, etching through the dielectric layer and the etch stop layer to form an opening exposing a top surface of the substrate, depositing an inhibitor film at a bottom of the opening, depositing a two-dimensional material layer on sidewalls of the opening, the two-dimensional material layer covering a top surface of the dielectric layer, removing the inhibitor film from the bottom of the opening, depositing a liner layer on the two-dimensional material layer and at the bottom of the opening, depositing a conductive material filling the opening, and performing a planarization process to remove a top portion of the conductive material and the liner layer to expose the two-dimensional material layer. The two-dimensional material layer remains covering the top surface of the dielectric layer. In some embodiments, the two-dimensional material layer includes hexagonal boron nitride. In some embodiments, the removing of the inhibitor film creates a gap exposing the etch stop layer. In some embodiments, the etch stop layer is in physical contact with both the two-dimensional material layer and the liner layer. In some embodiments, the depositing of the two-dimensional material layer includes a plasma-enhanced atomic layer deposition (PE-ALD) process or a chemical vapor deposition (CVD) process. In some embodiments, the two-dimensional material layer has a thermal conductivity great than about 10 W/m·K.

In yet another exemplary aspect, the present disclosure is directed to an interconnect structure. The interconnect structure includes a first conductive feature in a first dielectric layer, an etch stop layer over the first conductive feature, a second dielectric layer over the etch stop layer, a second conductive feature extending through the second dielectric layer and the etch stop layer and landing on the first conductive feature, and a thermal conductive barrier layer interposing the second conductive feature and the second dielectric layer. The thermal conducive barrier layer has a horizontal portion in direct contact with a top surface of the second dielectric layer. In some embodiments, the second conductive feature includes a liner layer separating the thermal conductive barrier layer from contacting the first conductive feature. In some embodiments, the thermal conductive barrier layer is an electrical insulating layer. In some embodiments, the thermal conductive barrier layer is in physical contact with the etch stop layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a conductive feature in a first dielectric layer;
forming a second dielectric layer over the conductive feature;
forming an opening in the second dielectric layer to expose a top surface of the conductive feature;
forming an inhibitor film at the top surface of the conductive feature;
depositing a thermal conductive layer having a first portion on sidewalls of the opening and a second portion on a top surface of second dielectric layer;
removing the inhibitor film to expose the top surface of the conductive feature;
depositing a conductive material in the opening and on the second portion of the thermal conductive layer;
removing a portion of the conductive material to expose the second portion of the thermal conductive layer; and
forming a third dielectric layer on the second portion of the thermal conductive layer and on the second dielectric layer.

2. The method of claim 1, wherein the depositing of the thermal conductive layer includes a reaction between a precursor and a reactant gas, and wherein the precursor includes a molecule containing a boron-nitride ring-like structure.

3. The method of claim 2, wherein the molecule is a borazine or a 1,3,5-Trimethylborazine.

4. The method of claim 2, wherein the reaction is conducted in a temperature less than about 500° C.

5. The method of claim 1, wherein the thermal conductive layer includes hexagonal boron nitride.

6. The method of claim 1, further comprising:
prior to the depositing of the conductive material, depositing a liner on the thermal conductive layer, wherein the liner fills a gap between the thermal conductive layer and the conductive feature formed after the removing of the inhibitor film.

7. The method of claim 6, wherein the liner separates the thermal conductive layer from physically contacting the conductive feature.

8. The method of claim 1, wherein the forming of the inhibitor film includes:
forming an initial inhibitor layer in a first solution; and
thickening the initial inhibitor layer to form the inhibitor film in a second solution that is different from the first solution.

9. The method of claim 1, wherein the thermal conductive layer separates the third dielectric layer from physically contacting the second dielectric layer.

10. The method of claim 1, wherein the thermal conductive layer is configured to block a metal element in the conductive material from diffusing into the second dielectric layer.

11. A method of forming a semiconductor structure, comprising:
forming an etch stop layer over a substrate;
depositing a dielectric layer over the etch stop layer;
etching through the dielectric layer and the etch stop layer to form an opening exposing a top surface of the substrate;
depositing an inhibitor film at a bottom of the opening;
depositing a two-dimensional material layer on sidewalls of the opening, wherein the two-dimensional material layer covers a top surface of the dielectric layer;
removing the inhibitor film from the bottom of the opening;
depositing a liner layer on the two-dimensional material layer and at the bottom of the opening;
depositing a conductive material filling the opening; and
performing a planarization process to remove a top portion of the conductive material and the liner layer to expose the two-dimensional material layer, wherein the two-dimensional material layer remains covering the top surface of the dielectric layer.

12. The method of claim 11, wherein the two-dimensional material layer includes hexagonal boron nitride.

13. The method of claim 11, wherein the removing of the inhibitor film creates a gap exposing the etch stop layer.

14. The method of claim 11, wherein the etch stop layer is in physical contact with both the two-dimensional material layer and the liner layer.

15. The method of claim 11, wherein the depositing of the two-dimensional material layer includes a plasma-enhanced atomic layer deposition (PE-ALD) process or a chemical vapor deposition (CVD) process.

16. The method of claim 11, wherein the two-dimensional material layer has a thermal conductivity great than about 10 W/m·K.

17. An interconnect structure, comprising:
a first conductive feature in a first dielectric layer;
an etch stop layer over the first conductive feature;
a second dielectric layer over the etch stop layer;
a second conductive feature extending through the second dielectric layer and the etch stop layer and landing on the first conductive feature; and
a thermal conductive barrier layer interposing the second conductive feature and the second dielectric layer, wherein the thermal conducive barrier layer has a horizontal portion in direct contact with a top surface of the second dielectric layer.

18. The interconnect structure of claim 17, wherein the second conductive feature includes a liner layer separating the thermal conductive barrier layer from contacting the first conductive feature.

19. The interconnect structure of claim 17, wherein the thermal conductive barrier layer is an electrical insulating layer.

20. The interconnect structure of claim 17, wherein the thermal conductive barrier layer is in physical contact with the etch stop layer.
